(19) United States
(12) Patent Application Publication
(10) Pub. No.: US 2010/0253320 A1
(43) Pub. Date: Oct. 7, 2010

(54) OPTICAL FIBER ELECTRIC CURRENT SENSOR AND ELECTRIC CURRENT MEASUREMENT METHOD

(75) Inventor: Kiyoshi Kurosawa, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Electric Power Company, Incorporated, Tokyo (JP)

(21) Appl. No.: 12/739,394

(22) PCT Filed: Apr. 24, 2008
(86) PCT No.: PCT/JP2008/057933

§ 371 Date: Apr. 22, 2010

(30) Foreign Application Priority Data
Oct. 23, 2007 (JP) 2007-275601

(51) Int. Cl. G01R 31/00

(52) U.S. Cl. 324/96

(57) ABSTRACT

An optical fiber electric current sensor includes a polarization splitter (13) that splits output light from a sensor fiber (11) into two polarization components of which polarization planes intersect with each other; and a signal processing unit (15) that converts the two split polarization components into first and second signals (Px) and (Py) by opto-electric conversion, multiplies a ratio (Sx) between direct current component and alternating current component of the first signal (Px) and a ratio (Sy) between direct current component and alternating current component of the second signal (Py) by different coefficients, and calculates a difference value therebetween.

### TECHNICAL FIELD

The present invention relates to an optical fiber electric current sensor and an electric-current measurement method for measuring an electric current using the Faraday effect by which an optical polarization plane of the light propagating through the optical fiber is rotated depending on a magnetic field.

Priority is claimed on Japanese Patent Application No. 2007-275601, filed on Oct. 23, 2007, the contents of which are incorporated herein by reference.

### BACKGROUND ART

Recently, optical fiber electric current sensors using optical fiber have come under scrutiny as electric current measurement devices for monitoring electric power equipment or the like.

In this optical fiber electric current sensor, the electric current is measured using the Faraday effect whereby a polarization plane of the light propagating through a magnetic medium is rotated in proportion to the magnitude of the magnetic field in a propagation direction thereof. The optical fiber is also a sort of magnetic medium. If the linearly-polarized light is incident to the optical fiber which is used as a sensor, and the optical fiber is placed near a conductive material through which a measurement current is flowing (i.e., a magnetic field generating source), then rotation (Faraday rotation) is generated in the polarization plane of the linearly-polarized light within the optical fiber due to the Faraday effect. At this moment, since magnetic fields are generated in proportion to the current, the rotation angle (Faraday rotation angle) of the polarization plane caused by the Faraday effect is proportional to the magnitude of the measurement current. In this regard, the magnitude of the current can be obtained by measuring the Faraday rotation angle. This is a principle of the optical fiber electric current sensor.

In order to measure the Faraday rotation angle, a method was employed, in which the light output from the optical fiber is received by a photodiode or the like and converted into an electric signal so that a predetermined signal processing is performed for the obtained electric signal (e.g., refer to Patent Document 1).

[Patent Document 1] JP-A-1107-270505

### DISCLOSURE OF INVENTION

### Problems to be Solved by the Invention

If the atmospheric temperature at a place where the optical fiber electric current sensor is provided is varied, an optical bias which is an operational point when the Faraday rotation angle is measured or a Verdet constant which is a material property value providing the sensitivity of the Faraday effect to the optical fiber may change. As a result, the Faraday rotation angle required by the aforementioned signal processing becomes in error. Under such influences, the measurement value of the electric current becomes dependent on the temperature, and it may be impossible to perform accurate measurement.

A purpose of the present invention is to reduce temperature dependency of the electric current measurement value in an optical fiber electric current sensor and an electric current measurement method in which an electric current is measured using Faraday effect.

### Means for Solving the Problem

According to an aspect of the present invention, there is provided an optical fiber electric current sensor which has sensor fiber and measures a measurement current by inputting linearly-polarized light to the sensor fiber and detecting a magnitude of the Faraday rotation applied to the linearly-polarized light by the magnetic field generated by the measurement current flowing through a conductive material provided around the sensor fiber, the optical fiber electric current sensor including: a polarization splitter that splits output light from the sensor fiber into two polarization components of which polarization planes intersect with each other; and a signal processing means that converts the two polarization components split by the polarization splitter into first and second signals by opto-electric conversion, multiplies a ratio between direct current (DC) and alternating current (AC) components of the first signal and a ratio between DC and AC components of the second signal by different coefficients, and calculates a difference value thereof, wherein a magnitude of the Faraday rotation is obtained based on the difference value calculated by the signal processing means.

In this aspect, a ratio Sx between DC and AC components of the first signal and a ratio Sy between DC and AC components of the second signal are obtained, and the obtained ratios Sx and Sy are multiplied by different coefficients. A difference value between both ratios is obtained. The Faraday rotation angle is obtained based on the obtained difference value. The aforementioned difference value changes depending on the temperature, and the manner of change is different depending on the coefficients multiplied by the ratios Sx and Sy. Therefore, by appropriately setting these coefficients, it is possible to reduce the temperature dependency of the obtained Faraday rotation angle, i.e., the temperature dependency of the electric current measurement value.

In the optical fiber electric current sensor of this aspect, the coefficients may be set such that a component that changes in a first order with respect to the temperature change of the difference value becomes zero.

The difference value includes a component that does not change with respect to the temperature change, a component that changes in a first order with respect to the temperature change, and a component that changes in a second order with respect to the temperature change, and so forth. In an area where the variation in the difference value caused by the temperature change is small, the first order component dominates the temperature dependency. By setting the coefficients such that the component that changes in a first order with respect to the temperature change in the difference value becomes zero, it is possible to reduce the temperature dependency of the electric current measurement value.

In the optical fiber electric current sensor of this aspect, one of the coefficients may be set to 1, and the other coefficient may be set to a value obtained by dividing a difference between a temperature dependency coefficient of an optical bias and a temperature dependency coefficient of a Faraday rotation in the sensor fiber by a sum thereof.

The component that changes in a first order with respect to the temperature change in the difference value becomes zero when the one of the coefficients is set to 1, and the other coefficient is set to a value obtained by dividing a difference between a temperature dependency coefficient of an optical bias and a temperature dependency coefficient of a Faraday rotation in the sensor fiber by a sum thereof. By setting the coefficients in this way, since the component that changes in a first order with respect to the temperature change of the difference value becomes zero, it is possible to reduce the temperature dependency of the electric current measurement value.

The optical fiber electric current sensor of this aspect may further include a temperature sensor that measures temperature, and a control unit that controls the aforementioned coefficients depending on the temperature measured by the temperature sensor.

Even when optimal values of the coefficients multiplied by the ratios Sx and Sy change depending on the temperature, it is possible to reduce the temperature dependency of the electric current measurement value across a wide temperature range by measuring the temperature and optimally controlling these coefficients depending on the temperature.

According to another aspect of the invention, there is provided an electric current measurement method for measuring a measurement current by inputting linearly-polarized light to sensor fiber and detecting a magnitude of Faraday rotation applied to the linearly-polarized light by a magnetic field generated by the measurement current flowing through a conductive material provided around the sensor fiber, the method including: splitting the output light from the sensor fiber into two polarization components of which polarization planes are perpendicular to each other; converting the two split polarization components into first and second signals by opto-electric conversion; multiplying a ratio between DC and AC components of the first signal and a ratio between DC and AC components of the second signal by different coefficients and calculating a difference value thereof; and obtaining a magnitude of the Faraday rotation based on the calculated difference value.

### ADVANTAGE OF THE INVENTION

According to the present invention, in the optical fiber electric current sensor and the electric current measurement method for measuring the electric current using the Faraday effect, it is possible to reduce the temperature dependency of the electric current measurement value. Accordingly, it is possible to perform the electric current measurement with excellent accuracy.

### BRIEF DESCRIPTION OF THE DRAWINGS

FIG. 1 is a block diagram illustrating a reflection type optical fiber electric current sensor according to the first embodiment of the invention.

FIG. 2 is a graph illustrating characteristics of electric signals Px and Py obtained by the optical receiver.

FIG. 3 is a block diagram illustrating a reflection type optical fiber electric current sensor according to the second embodiment of the invention.

FIG. 4 is a block diagram illustrating a reflection type optical fiber electric current sensor according to the third embodiment of the invention.

### DESCRIPTION OF THE REFERENCE SYMBOLS

11 . . . SENSOR FIBER
12 . . . OPTICAL CIRCULATOR
13 . . . POLARIZATION SPLITTER
14 . . . FARADAY ROTOR
15 . . . SIGNAL PROCESSING UNIT
16 . . . OPTICAL RECEIVER FIBER
17 . . . TEMPERATURE SENSOR
21 . . . LIGHT SOURCE
22 . . . OPTICAL TRANSMISSION FIBER
151 . . . OPTICAL RECEIVER
152 . . . DIVIDER
153 . . . SIGN INVERTER
154 . . . VARIABLE GAIN UNIT
155 . . . ADDER
156 . . . CONTROLLER
157 . . . VARIABLE GAIN UNIT

### DETAILED DESCRIPTION OF THE PREFERRED EMBODIMENTS

Hereinafter, embodiments of the present invention will be described in detail with reference to the accompanying drawings.

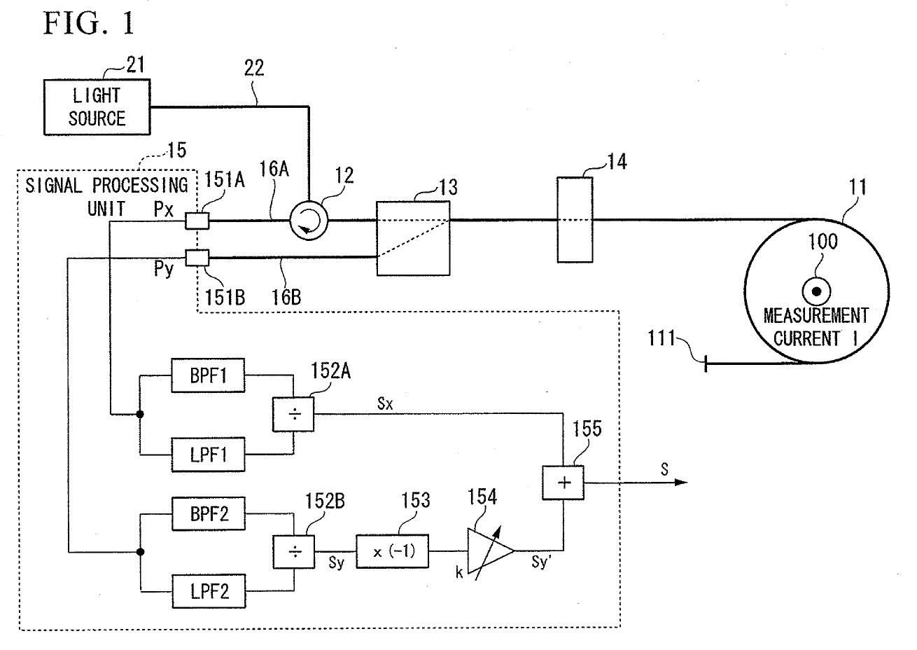

FIG. 1 is a block diagram illustrating a reflection type optical fiber electric current sensor according to the first embodiment of the invention.

Referring to FIG. 1, the optical fiber electric current sensor includes sensor fiber 11, an optical circulator 12, a polarization splitter 13, a Faraday rotor 14, and a signal processing unit 15. The signal processing unit 15 includes optical receivers 151A and 151B, band pass filters BPF1 and BPF2, low pass filters LPF1 and LPF2, dividers 152A and 152B, a sign inverter 153, a variable gain unit 154, and an adder 155.

The sensor fiber 11 is arranged to revolve around a conductive material 100 such as an electric cable through which flows the measurement current I which is a target to be measured. Lead glass fiber which is an optical fiber having a large Verdet constant that determines the magnitude of the Faraday effect may be employed in the sensor fiber 11. The Faraday rotor 14 is installed in one end of the sensor fiber 11, and a reflector (mirror) 111 is formed in the other end of the sensor fiber 11 by depositing a metal thin film or the like. The Faraday rotor 14 and the polarization splitter 13 are connected to each other with optical fiber. The polarization splitter 13 and the optical circulator 12 are connected to each other with optical fiber. The optical circulator 12 is arranged in a direction such that the light supplied from the light source 21 through the optical transmission fiber 22 is transmitted to the sensor fiber 11 side. The signal processing unit 15 has two optical receivers 151A and 151B as an input unit. One of the optical receivers 151A is connected to a terminal where the transmitted light is output at the sensor fiber 11 side of the optical circulator 12 by the optical receiver fiber 16A. The other optical receiver 151B is connected to the polarization splitter 13 by the optical receiver fiber 16B.

For the optical fiber electric current sensor configured in this way, the light from the light source 21 is incident to the polarization splitter 13 via the optical transmission fiber 22 and the optical circulator 12. This light is converted into linearly-polarized light of which vibration directions of electric fields are aligned in a single direction (e.g., in the principal axis direction of the polarization splitter 13) by the polarization splitter 13 and input to the Faraday rotor 14. The Faraday rotor 14 includes a permanent magnet and a ferromagnetic garnet having ferromagnetic crystals magnetically saturated by the permanent magnet to apply the Faraday rotation of approximately 22.5° in a single unidirectional trip to the light passing through the ferromagnetic garnet. The linearly-polarized light output from the Faraday rotor 14 is input to the sensor fiber 11. At the revolving portion of the sensor fiber 11, the linearly-polarized light is subjected to the Faraday rotation due to the magnetic field generated around the measurement current I flowing through the conductive material 100, and the polarization plane thereof is rotated by the Faraday rotation angle proportional to the magnitude of the magnetic field.

The light propagating through the sensor fiber 11 is reflected at the reflector 111 and travels through the revolving portion once again so as to be subjected to the Faraday rotation and input to the Faraday rotor 14. The Faraday rotation of approximately 22.5° is further generated when the light passes through the Faraday rotor 14 once again. As a result, the Faraday rotation of a total of 45° in a round trip can be generated by the Faraday rotor 14 for the light propagating through the sensor fiber 11. In other words, an optical bias of 45° is established in this optical fiber electric current sensor. The light passing through the Faraday rotor 14 is guided again into the polarization splitter 13 and split into two polarization components of which polarization directions are substantially perpendicular to each other (i.e., the principal axis direction of the polarization splitter 13 and the direction perpendicular thereto). One of the split components is received by the optical receiver 151A via the optical circulator 12 and the optical receiver fiber 16A and converted into an electric signal Px proportional to the light intensity thereof. Meanwhile, the other component is received by the optical receiver 151B via the optical receiver fiber 16B and converted into an electric signal Py proportional to the light intensity thereof.

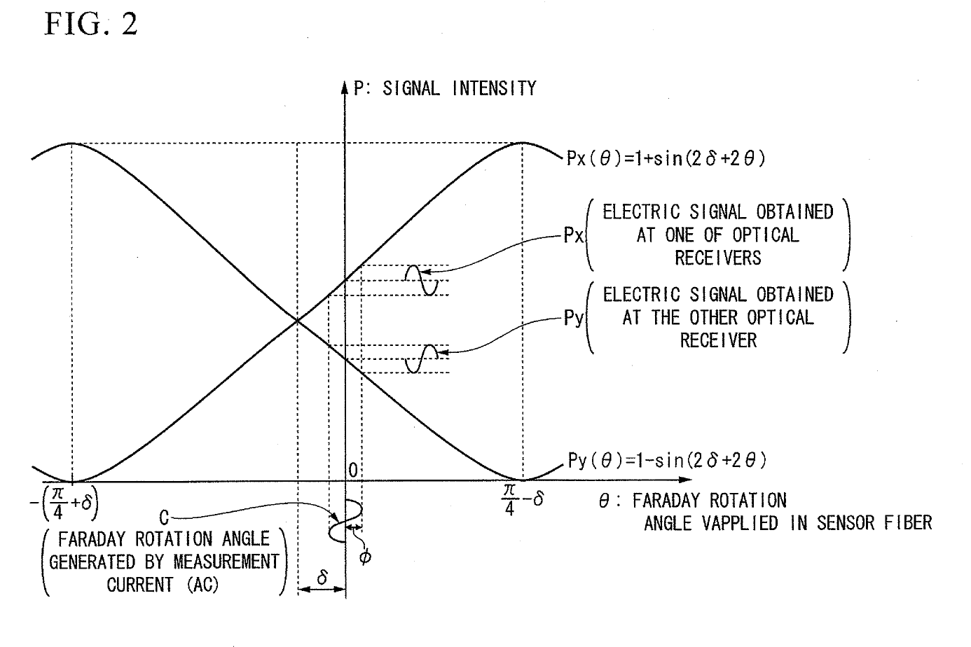

Here, it is assumed that the measurement current I measured by this optical fiber electric current sensor has (only) the alternating current (AC) component. In this case, since the Faraday effect applied to the light within the sensor fiber 11 also reflects this AC component, the aforementioned electric signals Px and Py include both the DC and AC components (refer to FIG. 2).

The electric signal Px from the optical receiver 151A is input to the band pass filter BPF1 and the low pass filter LPF1. The band pass filter BPF1 extracts the AC component included in the electric signal Px and outputs it to the divider 152A. The low pass filter LPF1 extracts the DC component included in the electric signal Px and outputs it to the divider 152A. The divider 152A outputs to the adder 155 a signal Sx representing a ratio between the DC and AC components obtained by dividing the input AC component by the DC component.

The electric signal Py from the optical receiver 151B is input to the band pass filter BPF2 and the low pass filter LPF2. As described above, the band pass filter BPF2 and the low pass filter LPF2 extract the AC and DC components, respectively, included in the electric signal Py and output them to the divider 152B. The divider 152B outputs to the sign inverter 153 the signal Sy representing a ratio between the DC and AC components, obtained by dividing the input AC component by the DC component. The sign inverter 153 inverts the sign of the signal Sy and outputs it to the variable gain unit 154. The variable gain unit 154 outputs to the adder 155 the signal Sy′ obtained by multiplying the input signal by the gain k.

The adder 155 adds the two input signals Sx and Sy′ and outputs the addition result as a signal S.

Next, an operation principle of the signal processing unit 15 will be described in detail using formulas.

FIG. 2 is a graph representing characteristics of the electric signals Px and Py (the intensity of the received light) obtained using the optical receivers 151A and 151B. In this graph, the abscissa denotes the Faraday rotation angle θ applied to the linearly-polarized light input to the sensor fiber 11, and the ordinate denotes the signal intensity P of each electric signal. The intensity of light arriving at each of the two optical receivers 151A and 151B is determined as described above based on the Faraday rotation angle θ applied at the sensor fiber 11 and the Faraday rotation angle applied by the Faraday rotor 14, i.e., the optical bias value. Generally, considering a case that the optical bias has a deviation δ from its setup value of 45°, the electric signals Px(θ) and Py(θ) can be expressed as functions of the Faraday rotation angle θ as shown in the following equations (1a) and (1b).

Px(θ)=1+sin(2δ+2θ) (1a)

Py(θ)=1−sin(2δ+2θ) (1b)

Here, since the measurement current I is an AC current, the Faraday rotation applied to the linearly-polarized light within the sensor fiber 11 by the measurement current I is oscillated at a frequency of the corresponding AC current around an angle of 0°. The amplitude of this oscillation is set to φ. In the drawing, the curve C illustrates a temporal change of the Faraday rotation angle generated by the measurement current I which is the AC current.

According to the curve C, as the Faraday rotation angle temporally changes from −φ to 0 to φ, the electric signal Px obtained by the optical receiver 151A sequentially changes as follows.

Px(−φ)=1+sin(2δ−2φ)

→Px(0)=1+sin(2δ)

→Px(φ)=1+sin(2δ+2φ)

As a result, the electric signal Px obtained according to the AC measurement current I becomes a signal oscillating at a frequency of the measurement current I as shown as the curve Px in the drawing. This signal has a magnitude of the DC component Px(0)=1+sin(2δ) and the amplitude of the AC component {Px(φ)−Px(−φ)}/2={sin(2δ+2φ)−sin(2δ−2φ)}/2. In an area where the deviation δ of the optical bias and the amplitude φ of the Faraday rotation caused by the sensor fiber 11 are sufficiently small (δ and φ<<1), the DC component Px_{DC} and the AC component Px_{AC} of the electric signal Px when the measurement current I is measured can be expressed as the following equations (2a) and (2b), respectively.

Px_{DC}=Px(0)≅1+2δ (2a)

Px_{AC}={Px(φ)−Px(−φ)}/2≅2φ (2b)

These equations (2a) and (2b) are output from the band pass filter BPF1 and the low pass filter LPF1, respectively.

Similarly, as the Faraday rotation angle temporally changes from −φ to 0 to φ according to the curve C, the electric signal Py obtained by the optical receiver 151B sequentially changes as follows.

Py(−φ)=1−sin(2δ−2φ)

→Py(0)=1−sin(2δ)

→Py(φ)=1−sin(2δ+2φ)

As a result, the electric signal Py obtained according to the AC measurement current I becomes a signal oscillating at a frequency of the measurement current I as shown as the curve Py in the drawing. This signal has a magnitude of the DC component Py(0)=1−sin(2δ) and an amplitude of the AC component {Py(−φ)−Py(φ)}/2={sin(2δ+2φ)−sin(2δ−2φ)}/2. Similarly, in the area where the condition (δ and φ<<1) is satisfied, the DC component Py_{DC} and the AC component Py_{AC} of the electric signal Py when the measurement current I is measured can be expressed as the following equations (3a) and (3b), respectively.

Py_{DC}=Py(0)≅1−2δ (3a)

Py_{AC}=−{Py(−φ)−Py(φ)}/2≅−2φ (3b),

where, the minus sign for the AC component Py_{AC} denotes an inverted phase with respect to the AC component Px_{AC}. The equations (3a) and (3b) represent the signals output from the band pass filter BPF2 and the low pass filter LPF2, respectively.

Based on the aforementioned equations (2a), (2b), (3a), and (3b), the signals Sx and Sy′ input to the adder 155 are expressed as the following equations (4a) and (4b), respectively.

$$\begin{matrix}Sx = \frac{{Px}_{A C}}{{Px}_{D C}} = \frac{2 φ}{1 + 2 δ} & ( 4 a ) \\ {Sy}^{′} = - k \cdot Sy = - k \cdot \frac{{Py}_{A C}}{{Py}_{D C}} = \frac{2 k φ}{1 - 2 δ} & ( 4 b )\end{matrix}$$

Therefore, the output signal S of the adder 155 can be expressed as the following equation (5).

$$S = Sx + {Sy}^{′} = \frac{2 φ}{1 + 2 δ} + \frac{2 k φ}{1 - 2 δ} \qquad ( 5 )$$

In the aforementioned equation (5), since δ and φ<<1, the high-order term is neglected. Then, the equation (5) becomes S=2(1+k)φ. Therefore, it is possible to obtain the Faraday rotation angle φ corresponding to the measurement current I based on this output signal S.

Here, the magnitude of the Faraday rotation applied at the sensor fiber 11 changes depending on the change of the atmospheric temperature because the Verdet constant of the sensor fiber 11 depends on the temperature. In addition, the optical bias caused by the Faraday rotor 14 also changes depending on the change of the atmospheric temperature because the Verdet constant of the ferromagnetic garnet depends on the temperature. Considering these facts, it is assumed that the amplitude φ of the Faraday rotation caused by the sensor fiber 11 and the deviation δ of the optical bias depend on the temperature as shown in the following equations (6a) and (6b).

δ=αT/2 (6a)

φ=(1+βT)φ₀ (6b),

where, α and β denote corresponding temperature dependency coefficients (known values), T denotes a temperature change amount from a reference temperature (e.g., 20° C.), and φ₀ denotes an amplitude of the Faraday rotation angle at the corresponding reference temperature.

Based on the aforementioned equations (5), (6a), and (6b), the output signal S of the adder 155 can be expressed as the following equation (7) as a function of the temperature change T.

$$S = \frac{2 {φ}_{0}}{1 - {α}^{2} {T}^{2}} \cdot [ ( 1 + k ) + \{ \begin{matrix}- ( α - β ) + \\ k ( α + β )\end{matrix} \} T - ( 1 - k ) αβ {T}^{2} ] \qquad ( 7 )$$

In the numerator of the equation (7), under the approximation of (δ and φ<<1), the first order term of the temperature change T is more dominated than the second-order term. In this regard, it is possible to reduce the temperature dependency of the output signal S obtained from the adder 155 by determining the gain k of the variable gain unit 154 such that the first order term of the temperature change T becomes zero. Such a gain k can be obtained based on the equation (7) and the following equation (8).

$$k = \frac{α - β}{α + β} \qquad ( 8 )$$

Therefore, the gain k obtained from the aforementioned equation (8) is set in the variable gain unit 154 of the optical fiber electric current sensor. At this moment, the output signal S of the adder 155 is expressed as the following equation (9).

$$S = \frac{1 - {β}^{2} {T}^{2}}{1 - {α}^{2} {T}^{2}} \cdot \frac{2 α}{α + β} \cdot 2 {φ}_{0} \qquad ( 9 )$$

Meanwhile, in the optical fiber electric current sensor of the related art, where the variable gain unit 154 is not provided, the output signal S of the adder 155 is expressed as the following equation (10) by setting k=1 in the aforementioned equation (7).

$$S = \frac{1 + β T}{1 - {α}^{2} {T}^{2}} \cdot 4 {φ}_{0} \qquad ( 10 )$$

In this manner, focusing on the numerators of the equations (9) and (10), in the optical fiber electric current sensor of the related art, the measurement value (the output signal S) of the Faraday rotation angle depends on the temperature change in the first-order term. On the contrary, in the optical fiber electric current sensor of the present invention, the measurement value depends on the temperature change in the second-order term. In the area where the condition (δ and φ<<1) is satisfied, the second-order term of the temperature change is sufficiently smaller than the first-order term. Therefore, in the optical fiber electric current sensor of the present invention, it is possible to reduce temperature dependency of the measured Faraday rotation angle. As a result, it is possible to reduce temperature dependency of the electric current measurement value.

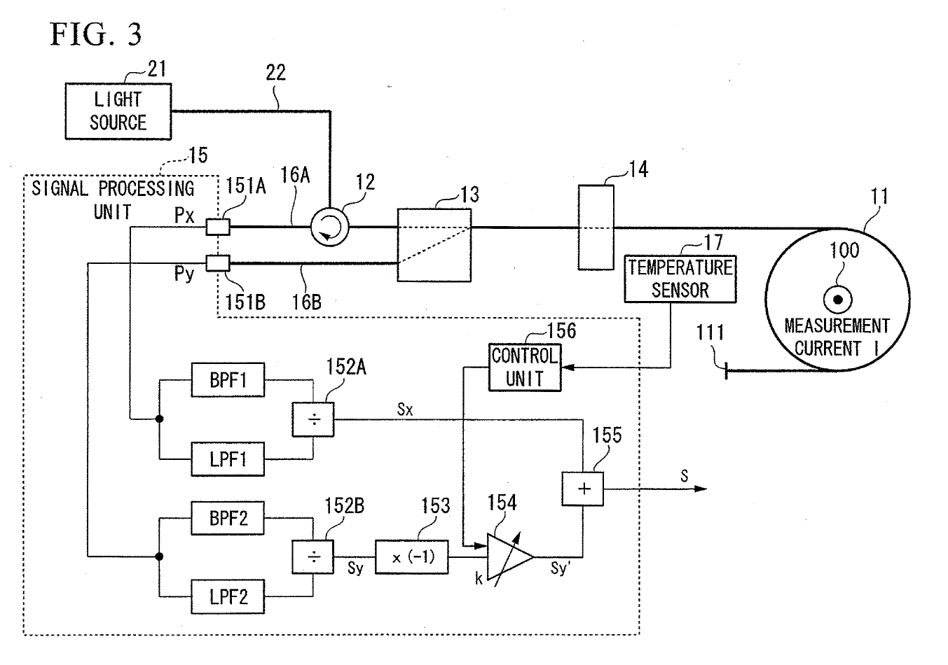

Next, a reflection type optical fiber electric current sensor according to the second embodiment of the present invention will be described with reference to the block diagram of FIG. 3.

This optical fiber electric current sensor further includes the temperature sensor 17 and the control unit 156 in addition to the aforementioned optical fiber electric current sensor of FIG. 1. Functionalities and operations of the elements except for the temperature sensor 17 and the control unit 156 are similar to those of the optical fiber electric current sensor of FIG. 1, and descriptions thereof will be omitted.

Referring to FIG. 3, the temperature sensor 17 is provided in a predetermined place within the optical fiber electric current sensor, for example, near the sensor fiber 11 or the Faraday rotor 14 to measure the temperature of the corresponding place and supply a signal representing the measured temperature to the control unit 156. The control unit 156 variably controls the gain k of the variable gain unit 154 depending on the temperature measured by the temperature sensor 17.

In the first embodiment described above, the first-order term of the temperature change T in the numerator of the equation (7) representing the temperature dependency of the output signal S becomes zero by setting the gain k to the fixed value provided in the equation (8). In the present embodiment, the gain k is set to a variable value as a function of the temperature change T so that the influence of the temperature change T can be compensated for in the entire equation (7) including the denominator and the numerator. Specifically, when c is set to any constant number, the equation (7) becomes S=2cφ₀, and the gain k for removing the temperature dependency is expressed as the following equation (11).

$$k ( T ) = \frac{c ( 1 - {α}^{2} {T}^{2} ) - \{ 1 - ( α - β ) T - αβ {T}^{2} \}}{1 + ( α + β ) T + αβ {T}^{2}} \qquad ( 11 )$$

In this regard, the control unit 156 calculates the gain k(T) at the corresponding measured temperature according to the equation (11) based on the known values α and β and the temperature change T from the reference temperature obtained from the temperature measured by the temperature sensor 17 and sets the obtained gain k(T) in the variable gain unit 154. As a result, it is possible to further reduce the temperature dependency in the measured Faraday rotation angle and still further reduce the temperature dependency of the electric current measurement value. Therefore, it is possible to perform the accurate electric current measurement without influence from the atmospheric temperature. It is preferable that the temperature sensor 17 is provided near the Faraday rotor 14 or the sensor fiber 11 to measure such a temperature.

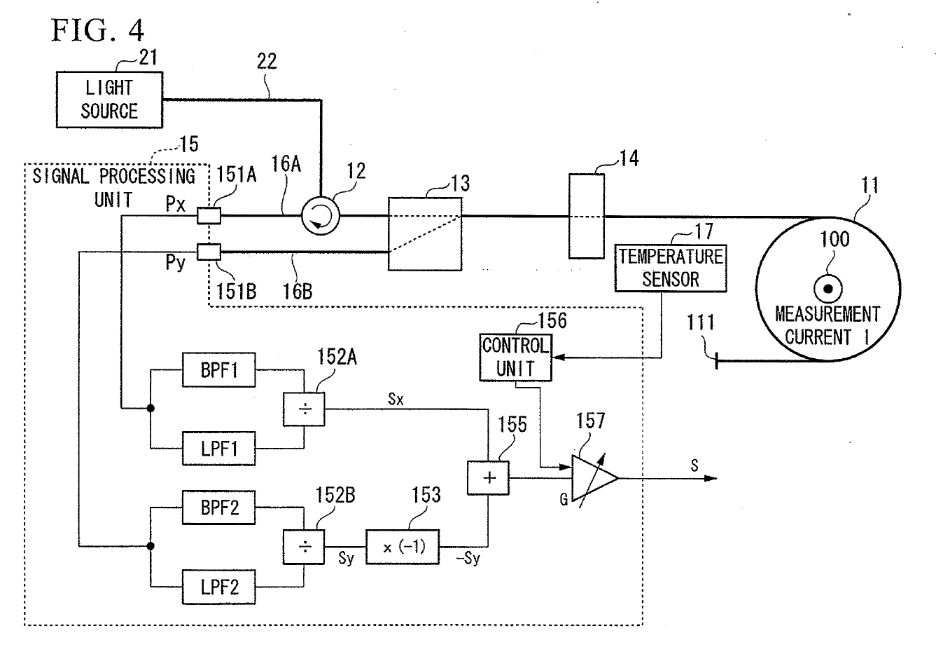

Next, the reflection type optical fiber electric current sensor according to the third embodiment of the present invention will be described with reference to the block diagram of FIG. 4.

In this optical fiber electric current sensor, the variable gain unit 157 which receives the output of the adder 155 is provided instead of the aforementioned variable gain unit 154 of FIG. 3, and the gain G of this variable gain unit 157 is variably controlled by the control unit 156 depending on the measurement temperature of the temperature sensor 17. In this configuration, the output signal S of the variable gain unit 157 may be obtained by setting the gain k of the equation (7) to 1 and multiplying the gain G in the right side as apparent from the elicitation process of the equation (7) described above. Therefore, the output signal is expressed as the following equation (12).

$$S = 4 {φ}_{0} \cdot \frac{1 + β T}{1 - {α}^{2} {T}^{2}} \cdot G \qquad ( 12 )$$

Even in the present embodiment, similar to the second embodiment, in order to compensate for the influence of the temperature change T in the entire equation (12), the gain G is set to a variable value as a function of the temperature change T. Specifically, when c is set to any constant number, the equation (12) becomes S=4cφ₀. Therefore, the gain G for removing the dependency on the temperature is expressed as the following equation (13).

$$G ( T ) = \frac{c ( 1 - {α}^{2} {T}^{2} )}{1 + β T} \qquad ( 13 )$$

In this regard, the control unit 156 obtains the gain G(T) at the corresponding measured temperature according to the equation (13) based on the known values α and β and the temperature change T from the reference temperature obtained from the temperature measured by the temperature sensor 17 and sets the obtained gain G(T) in the variable gain unit 157. As a result, similar to the second embodiment, it is possible to further reduce the temperature dependency in the measured Faraday rotation angle and still further reduce the temperature dependency of the electric current measurement value. Therefore, it is possible to perform the accurate electric current measurement without influence from the atmospheric temperature.

While the embodiments of the present invention have been described with reference to the accompanying drawings, detailed configurations are not limited to those described above. Instead, various modifications in design or the like may be made without departing from the scope of the present invention.

The present invention is not limited to the reflection type optical fiber electric current sensor, but may also be applied to the transmission type optical fiber electric current sensor. In the transmission type optical fiber electric current sensor, the polarization splitter 13 and the signal processing unit 15 are provided in the opposite side to the light source 21 of the sensor fiber 11. In the transmission type optical fiber electric current sensor, the optical bias may be set by using an optical polarizer for transmitting only a single component of the vibration direction of the electric field of the incident light or a wavelength plate for rotating the polarization plane of the transmitted linearly-polarized light to a predetermined angle instead of the Faraday rotor 14 used in the reflection type optical fiber electric current sensor. In this case, the deviation δ of the optical bias is generated by such an optical polarizer or wavelength plate. However, the aforementioned principle is similarly applied.

While it has been described that the gain k is multiplied by only the signal Sy from the divider 152B, the signal processing unit 15 may be configured such that different coefficients are multiplied by the signal Sx from the divider 152A and the signal Sy from the divider 152B.

1. An optical fiber electric current sensor comprising:
sensor fiber that surrounds a conductive material and receives linearly-polarized light;
a polarization splitter that splits output light from the sensor fiber into two polarization components of which polarization planes intersect with each other; and
a signal processing unit that converts the two polarization components from the polarization splitter into first and second signals by opto-electric conversion, multiplies a ratio between direct current component and alternating current component of the first signal and a ratio between direct current component and alternating current component of the second signal by different coefficients, and calculates a difference value therebetween,
wherein a magnitude of the Faraday rotation applied to the linearly-polarized light is obtained based on the difference value calculated by the signal processing unit.

2. The optical fiber electric current sensor according to claim 1, wherein the coefficients are set such that a component that changes in a first order with respect to a temperature change of the difference value becomes zero.

3. The optical fiber electric current sensor according to claim 1, wherein one of the coefficients is set to 1, and the other coefficient is set to a value obtained by dividing a difference between a temperature dependency coefficient of an optical bias and a temperature dependency coefficient of Faraday rotation in the sensor fiber by a sum thereof.

4. The optical fiber electric current sensor according to any one of claims 1 to 3, further comprising:
a temperature sensor that measures temperature; and
a control unit that controls the coefficients depending on temperature measured by the temperature sensor.

5. An electric current measurement method comprising:
splitting output light from a sensor fiber that surrounds a conductive material and receives linearly-polarized light into two polarization components of which polarization planes intersect with each other;
converting the two split polarization components into first and second signals by opto-electric conversion;
multiplying a ratio between direct current component and alternating current component of the first signal and a ratio between direct current component and alternating current component of the second signal by different coefficients and calculating a difference value thereof; and
obtaining a magnitude of Faraday rotation applied to the linearly-polarized light based on the calculated difference value.
